(19) United States
(12) Patent Application Publication
(10) Pub. No.: US 2021/0367194 A1
(43) Pub. Date: Nov. 25, 2021

(54) OLED PANEL, DISPLAY APPARATUS AND PANEL PACKAGING METHOD

(71) Applicant: BOE Technology Group Co., Ltd., Beijing (CN)

(72) Inventor: Donghui Yu, Beijing (CN)

(73) Assignee: BOE Technology Group Co., Ltd., Beijing (CN)

(21) Appl. No.: 16/962,334

(22) PCT Filed: Dec. 20, 2019
(86) PCT No.: PCT/CN2019/127130

§ 371 Date: Jul. 15, 2020

(30) Foreign Application Priority Data
Jan. 8, 2019 (CN) 201910017128.1

(51) Int. Cl. H01L 51/52; H01L 51/56; H01L 27/32

(52) U.S. Cl. CPC H01L 51/5246; H01L 27/32; H01L 51/56

(57) ABSTRACT

Embodiments of the present disclosure propose an OLED panel, a panel packaging method, and a display apparatus. In an embodiment, the OLED panel includes: a first substrate on which an OLED device is provided; a second substrate opposite to the first substrate; a box dam connected to the first substrate and the second substrate, wherein the OLED device is located in a sealed region formed by the box dam, the first substrate and the second substrate; wherein an adhesion reinforcement layer is provided between the box dam and the first substrate or between the box dam and the second substrate, or adhesion reinforcement layers are respectively provided between the box dam and the first substrate and between the box dam and the second substrate.

### CROSS-REFERENCE TO RELATED APPLICATION

This application claims priority of Chinese Patent Application No. 201910017128.1 filed on Jan. 8, 2019 in China National Intellectual Property Administration, the disclosure of which is incorporated herein by reference in entirety.

### TECHNICAL FIELD

Embodiments of the present disclosure relate to the field of display technology, and in particular, to an organic light emitting diode (OLED) panel, a display apparatus, and a panel packaging method.

### BACKGROUND

Organic electroluminescent devices, that is, organic light emitting diodes (OLEDs), have the characteristics of low power consumption, light weight, high brightness, and achievable flexibility, and therefore they have received extensive attention. However, the OLED devices are sensitive to water vapor, the intrusion of water vapor often causes the problem of decay in life. Therefore, a good package is often required to block water vapor and oxygen.

At present, there are many ways to package the OLED devices. Among them, a box dam and sealant (Dam&Fill) packaging method can be used for both bottom-emitting devices and top-emitting devices, and it is one of the commonly used packaging methods. The box dam and sealant packaging structure refers to that a box dam, a first substrate and a second substrate are utilized to form a sealed region of the OLED device, and the sealed region is filled with the sealant. Since the box dam material functions as a first barrier structure that directly contacts the external water vapor, the sealing effect of the box dam directly affects the water vapor barrier effect.

### SUMMARY

In an aspect, embodiments of the present disclosure provide an OLED panel, comprising:

a first substrate on which an OLED device is provided;

a second substrate opposite to the first substrate:

a box dam connected to the first substrate and the second substrate,

wherein the OLED device is located in a sealed region formed by the box dam, the first substrate and the second substrate;

wherein an adhesion reinforcement layer is provided between the box dam and the first substrate or between the box dam and the second substrate, or adhesion reinforcement layers are respectively provided between the box dam and the first substrate and between the box dam and the second substrate.

In an exemplary embodiment, an adhesive force of a material of the adhesion reinforcement layer is greater than or equal to twice an adhesive force of a material of the box dam.

In an exemplary embodiment, a material of the adhesion reinforcement layer comprises one of the following: a resin-based material, an acrylic-based material, or a polyester material.

In an exemplary embodiment, fine particles are provided in the adhesion enhancement layer.

In an exemplary embodiment, a material of the fine particles comprises an inorganic material.

In an exemplary embodiment, the adhesion reinforcement layer is in a dotted arrangement or a linear arrangement in a plane parallel to the first substrate and/or the second substrate.

In an exemplary embodiment, in a plane perpendicular to the first substrate and/or the second substrate, the adhesion reinforcement layer has a cross-sectional shape of rectangle, semicircle, trapezoid, or triangle.

In an exemplary embodiment, in a plane perpendicular to the first substrate, a contact surface of the adhesion reinforcement layer and the first substrate has a concave-convex structure; and/or, in a plane perpendicular to the second substrate, a contact surface of the adhesion reinforcement layer and the second substrate has a concave-convex structure.

In another aspect, embodiments of the present disclosure provide an OLED display apparatus, comprising the OLED panel according to any one of the abovementioned embodiments.

In yet another aspect, embodiments of the present disclosure provide an OLED panel packaging method, comprising:

providing a first substrate on which an OLED device is formed, and a second substrate, an adhesion enhancement layer(s) being formed on the first substrate and/or the second substrate;

forming a box dam on the second substrate:

aligning the first substrate with the second substrate and fixing the first substrate and the second substrate, so that the OLED device is located in a sealed region formed by the box dam, the first substrate, and the second substrate.

In an exemplary embodiment, the adhesion enhancement layer is formed by spot coating, spray coating, or coating.

In an exemplary embodiment, an adhesive force of a material of the adhesion reinforcement layer is greater than or equal to twice an adhesive force of a material of the box dam.

In an exemplary embodiment, a material of the adhesion reinforcement layer comprises one of the following: a resin-based material, an acrylic-based material, or a polyester material.

In an exemplary embodiment, the adhesion reinforcement layer is in a dotted arrangement or a linear arrangement in a plane parallel to the first substrate and/or the second substrate, in a plane perpendicular to the first substrate and/or the second substrate, the adhesion reinforcement layer has a cross-sectional shape of rectangle, semicircle, trapezoid, or triangle.

In an exemplary embodiment, in a plane perpendicular to the first substrate, a contact surface of the adhesion reinforcement layer and the first substrate has a concave-convex structure; and/or in a plane perpendicular to the second substrate, a contact surface of the adhesion reinforcement layer and the second substrate has a concave-convex structure.

In still another aspect, embodiments of the present disclosure provide an OLED panel packaging method, comprising:

providing a first substrate and forming an OLED device on the first substrate;

forming a first adhesion enhancement layer around the OLED device;

providing a second substrate and forming a box dam and a sealant on the second substrate;

aligning the second substrate on which the box dam and the sealant has been formed with the first substrate to achieve a connection between the box dam and the first adhesion reinforcement layer; and

curing the connection between the box dam and the first adhesion reinforcement layer, so that the sealant is filled in a sealed region formed by the box dam, the first substrate and the second substrate.

In a further aspect, embodiments of the present disclosure provide an OLED panel packaging method, comprising:

providing a first substrate and forming an OLED device on the first substrate;

providing a second substrate, forming a second adhesion reinforcement layer on the second substrate, forming a box dam on the second adhesion reinforcement layer, and forming a sealant within the box dam; and

aligning the first substrate with the second substrate to achieve a connection between the box dam and a first adhesion reinforcement layer, and curing the connection between the box dam and the first adhesion reinforcement layer, so that the sealant is filled in a sealed region formed by the box dam, the first substrate and the second substrate.

In a yet further aspect, embodiments of the present disclosure provide an OLED panel packaging method, comprising:

providing a first substrate and forming an OLED device on the first substrate; forming a first adhesion enhancement layer around the OLED device;

providing a second substrate, forming a second adhesion reinforcement layer on the second substrate, forming a box dam on the second adhesion reinforcement layer, and forming a sealant within the box dam;

aligning the second substrate on which the box dam and the sealant has been formed with the first substrate to achieve a connection between the box dam and the first adhesion reinforcement layer, and

curing the connection between the box dam and the first adhesion reinforcement layer, so that the sealant is filled in a sealed region formed by the box dam, the first substrate and the second substrate.

Other features and advantages of the present disclosure will be described in the subsequent embodiments of the specification, and will partly become obvious from the embodiments of the specification, or they may be learned from the implementation of the present disclosure. The objects and other advantages of the embodiments of the present disclosure may be realized and obtained by the structures particularly described in the specification, claims, and drawings of the present disclosure.

### BRIEF DESCRIPTION OF THE DRAWINGS

The drawings are provided for a further understanding of the technical solutions of the present disclosure, and constitute a part of the specification. They are provided to explain the technical solutions of the present disclosure together with the embodiments of the present disclosure, but do not constitute any limitation on the technical solutions of the present disclosure. The shapes and sizes of the components in the drawings do not reflect the true scale, and they are just intended to schematically illustrate the present disclosure.

FIG. 1 is a schematic view of a packaging structure of an OLED panel according to an embodiment of the present disclosure;

FIG. 2 shows an example of a dotted arrangement of adhesion reinforcement layer in the embodiment shown in FIG. 1;

FIGS. 3a to 3b show examples of a linear arrangement of adhesion reinforcement layer in the embodiment shown in FIG. 1;

FIGS. 4a to 4f show examples of a concave-convex structure of the adhesion reinforcement layer in the embodiment shown in FIG. 1;

FIG. 5 is a schematic view of a package structure of an OLED panel according to another embodiment of the present disclosure;

FIG. 6 is a schematic view of a package structure of an OLED panel according to yet another embodiment of the present disclosure;

FIG. 7 is a fundamental flowchart of a packaging method according to an embodiment of the present disclosure;

FIG. 8 is a flowchart of an OLED panel packaging method according to an exemplary embodiment of the present disclosure;

FIG. 9 is a flowchart of an OLED panel packaging method according to another exemplary embodiment of the present disclosure; and

FIG. 10 is a flowchart of an OLED panel packaging method according to yet another exemplary embodiment of the present disclosure.

### DETAILED DESCRIPTION OF EMBODIMENTS

The specific implementation of the present disclosure will be described in further detail below with reference to the accompanying drawings and embodiments. The following embodiments are provided for illustrating the present disclosure, but will not limit the scope of the present disclosure. It should be noted that the embodiments and the features in the embodiments in the present disclosure may be arbitrarily combined with each other without conflict.

In order to improve the sealing effect of the box dam, the box dam is usually made from a material with high adhesiveness to ensure a reliable connection between the box dam and the substrate. The inventors of the present application have found that the coating properties of the high-adhesion materials are poor. For long-distance box dam coating, not only the coating difficult is large, but also the coating stability is poor and the yield is low, which makes the box dam have a lower sealing effect. At present, it is still very difficult to develop box dam materials with good adhesion and good coating property.

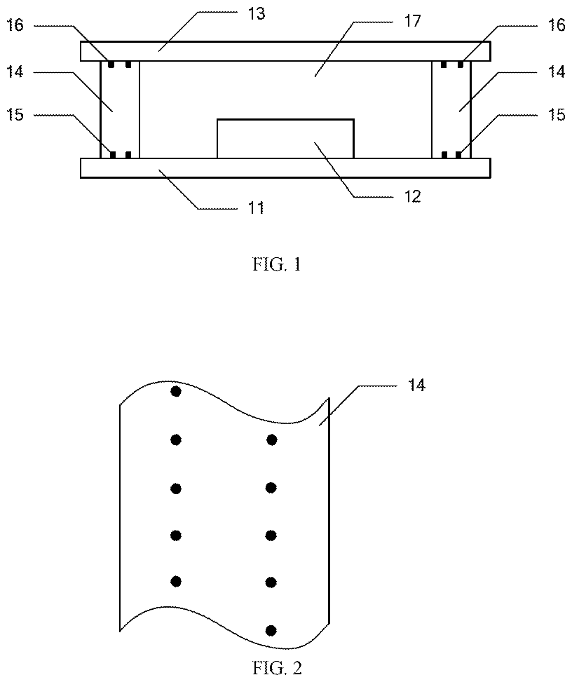

According to an embodiment of the present disclosure, an OLED panel is provided, as shown in FIG. 1, it includes:

a first substrate 11 provided with an OLED device 12;

a second substrate 13 disposed opposite to the first substrate 11; and a box dam 14 connected to the first substrate 11 and the second substrate 13.

The OLED device 12 is located in a sealed region formed by the box dam 14, the first substrate 11, and the second substrate 13; an adhesion reinforcement layer(s) 15, 16 are/is provided between the box dam 14 and the first substrate 11 and/or between the box dam 14 and the second substrate 13.

In the example shown in FIG. 1, an adhesion reinforcement layer 15, 16 is provided both between the box dam 14 and the first substrate 11 and between the box dam 14 and the second substrate 13. A first adhesion reinforcement layer 15 is provided between the box dam 14 and the first substrate 11, and a second adhesion reinforcement layer 16 is provided between the box dam 14 and the second substrate 13. The shape of the adhesion reinforcement layers is shown in FIG. 1 only as an example.

A sealant 17 is filled in the sealed region formed by the box dam 14, the first substrate 11 and the second substrate 13.

By providing an adhesion reinforcement layer between the box dam and the substrate, on the one hand, the adhesion reinforcement layer can be used to improve the sealing effect of the box dam, to effectively improve the reliability of the sealing structure, on the other hand, it can reduce the difficulty of coating the box dam, thereby providing a sealing structure having good adhesion and good coating property.

This embodiment describes a solution in which a first adhesion reinforcement layer 15 is provided between the box dam 14 and the first substrate 11, and a second adhesion reinforcement layer 16 is provided between the box dam 14 and the second substrate 13.

The adhesion enhancement layer described below includes a first adhesion enhancement layer 15 and a second adhesion enhancement layer 16.

According to an embodiment of the present disclosure, the adhesive force of the material of the adhesion reinforcement layer is greater than the adhesive force of the material of the box dam. In an exemplary embodiment, the adhesive force of the material of the adhesion reinforcement layer is greater than or equal to twice the adhesive force of the box dam. For example, if the adhesion force of the box dam is a, then the adhesion force of the material of the sealing material layer is greater than or equal to 2a. For example, the adhesive force of the material of the adhesion reinforcement layer may be greater than 50 kg/cm².

The greater the adhesion force of the material of the adhesion reinforcement layer is, the stronger the adhesion force between the box dam and the substrate is.

In an exemplary embodiment, the material of the adhesion reinforcement layer includes one of the following: a resin-based material, an acrylic-based material, or a polyester material. These materials have better adhesion and lower water vapor transmission rate (WVTR) than conventional materials. Due to its high adhesiveness high requirement is raised for the adhesive application equipment, and a short-distance coating can be used. If a short-distance coating is used, there is no need for long-distance stability, which can reduce the demand for the equipments.

In an exemplary embodiment, the material of the adhesion enhancement layer may further include fine particles. The material of the fine particles may include inorganic materials, for example, inorganic particles, to form a denser structure without taking into account coating property.

According to some embodiments of the present disclosure, in a plane parallel to the first substrate and/or the second substrate, the adhesion reinforcement layer is in a dotted arrangement or a linear arrangement. In a plane perpendicular to the first substrate and/or the second substrate, the cross-sectional shape of the adhesion reinforcement layer includes a rectangle, a semicircle, a trapezoid, or a triangle. In an exemplary embodiment, the first adhesion reinforcement layer 15 is arranged in a dot shape or a line shape in a plane that is in contact with the first substrate 11 and parallel to the first substrate 11; the cross-sectional shape of the first adhesion reinforcement layer 15 includes a rectangle, a semicircle, a trapezoid, or a triangle in a plane that is in contact with the first substrate 11 and perpendicular to the first substrate 11. Similarly, the second adhesion reinforcement layer 16 is in a dotted arrangement or a linear arrangement in a plane that is in contact with the second substrate 13 and parallel to the second substrate 13; the cross-sectional shape of the second adhesion reinforcement layer 16 includes a rectangle, a semicircle, a trapezoid, or a triangle in a plane that is in contact with the second substrate 13 and perpendicular to the second substrate 13.

The dotted arrangement may refer to, for example, uniformly-arranged dots, as shown in FIG. 2, these dots may be arranged in a linear form, or may be arranged in a matrix. The dots arranged linearly in FIG. 2 may include two columns as shown in the figure, or may include one column or more than two columns.

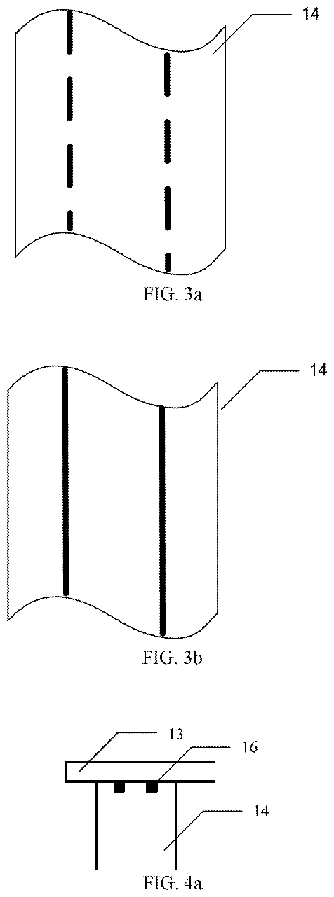

The linear arrangement may refer to, for example, the arrangement shown in FIG. 3a or the arrangement shown in FIG. 3b. It may be a straight line, a polyline, or a curve. Similarly, the lines shown in FIGS. 3a and 3b may include two columns of lines as shown in the figure, or may include one column or more than two columns.

In an exemplary embodiment, the contact surface of the adhesion reinforcement layer and the box dam and/or the contact surface of the adhesion reinforcement layer and the substrate have/has a concave-convex structure. For example, in a plane perpendicular to the first substrate 11, the contact surface of the first adhesion reinforcement layer 15 and the first substrate 11 has a concave-convex structure, and for example, in a plane perpendicular to the first substrate 11, the contact surface of the first adhesion reinforcement layer 15 and the box dam 14 has a concave-convex structure; similarly, for example, in a plane perpendicular to the second substrate 13, the contact surface of the second adhesion reinforcement layer 16 and the second substrate 13 has a concave-convex structure, and for example, in a plane perpendicular to the second substrate 13, the contact surface of the second adhesion reinforcement layer 16 and the box dam 14 has a concave-convex structure.

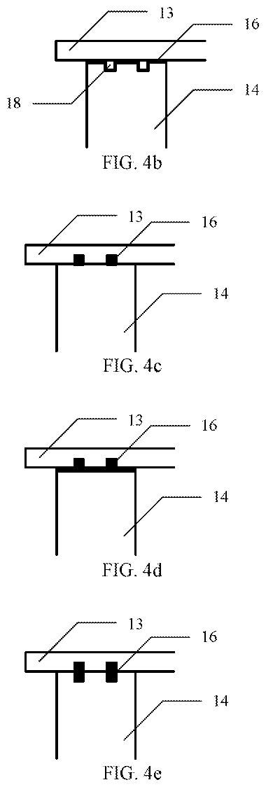

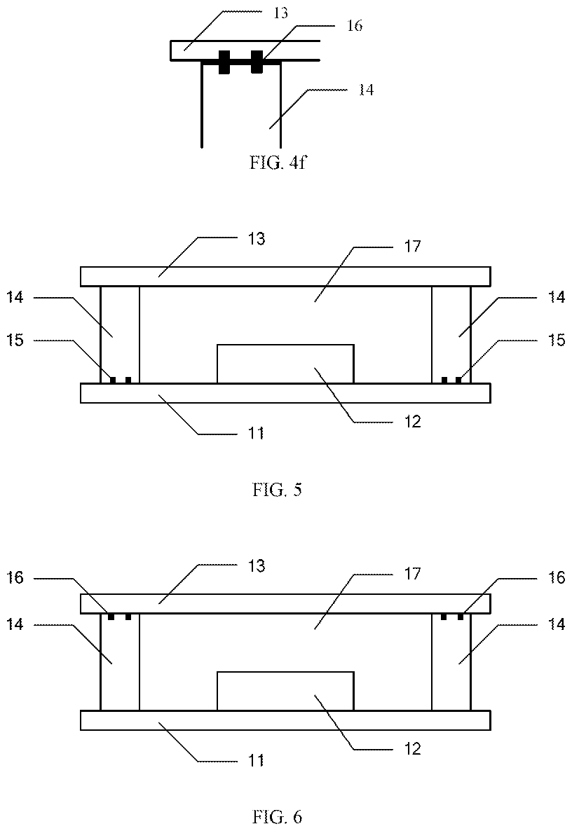

The concave-convex structure refers to the concave-convex structure of the cross-section of the adhesion reinforcement layer viewed from a direction perpendicular to the first substrate or the second substrate. Taking the contact surface of the box dam 14 and the second substrate 13 as an example, as shown in FIG. 4a, in the example shown in FIG. 4a, the adhesion reinforcement layer 16 is formed on the surface of the second substrate 13 opposite to the box dam 14 to form a convex structure. In this example, there are two convex structures. In other examples, there may be only one convex structure, or there may be more than two convex structures. In the foregoing embodiments, the convex structure is composed of the adhesion reinforcement layer, that is, the convex structure is formed by coating the adhesion reinforcement layer on the second substrate 13, and the shape of the adhesion reinforcement layer is, for example, rectangular or semicircular, etc. In other embodiments, the convex structure may also be composed of a protrusion 18 provided separately, as shown in FIG. 4b. In the example shown in FIG. 4b, convex structures 18 are formed on the surface of the second substrate 13 opposite to the box dam 14, and an adhesion reinforcement layer 16 is formed above the convex structures. In the example of FIG. 4b, there are two protrusions. In other examples, there may be only one protrusion, or there may be more than two protrusions. In addition to the above embodiments, the concave-convex structure may also be realized by etching to form grooves in the surface of the substrate. As shown in FIG. 4c, the adhesion reinforcement layer 16 is disposed in the grooves in the surface of the second substrate 13 opposite to the box dam 14, to constitute convex structures. In this example, the cross-section of the groove is rectangular. In other examples the cross-section of the groove may also be other shapes, such as a semicircle, a trapezoid, or a triangle. In order to enhance the adhesion, as shown in FIG. 4d, in addition to providing an adhesion reinforcement layer in the grooves, an adhesion reinforcement layer may also be provided on other contact surfaces of the substrate and the box dam. In the example of FIG. 4d, there are two grooves in the second substrate 13. In other examples, there may be only one groove, or there may be more than two grooves. The above convex structure (the convex structure may be the adhesion reinforcement layer itself or the protrusion) and the groove structure may also be used in combination, as shown in FIG. 4e, in FIG. 4e, the groove and the convex structure are rightly opposite to each other, in other embodiments, the groove and the convex structure may also be staggered, and the number of the grooves and the number of the protrusions are not limited, they may be the same or different. On this basis, in order to improve the adhesion, adhesion reinforcement layers may also be provided on the other contact surfaces of the substrate and the box dam, as shown in FIG. 4f.

By forming the concave-convex structure, the contact area of the box dam and the substrate can be increased, thereby improving the adhesion force. The above-mentioned embodiments of FIGS. 4a to 4f are described by taking the contact surface of the box dam 14 and the second substrate 13 as an example. The contact surface of the box dam 14 and the first substrate 11 may refer to the foregoing embodiments.

In the OLED panel proposed in this embodiment, in view of the material of the box dam with poor coating stability, a high-adhesive material is used to create a high-adhesive adhesion reinforcement layer. By means of the good adhesion of the adhesion reinforcement layer, it increases the contact area and adhesion force of the box dam and the substrate, improves the sealing effect of the box dam, effectively improves the level of reliability, and at the same time it reduce the difficulty of development in the material of box dam. In addition, since the adhesion reinforcement layer can be coated in a short-distance way, the coating difficulty is low, and it has good adhesion, thereby reducing the coating difficulty of the box dam.

According to another embodiment of the present disclosure, an OLED panel is provided. This embodiment is an extension of the aforementioned embodiment shown in FIG. 1, it is substantially the same as the main structure of the aforementioned embodiment shown in FIG. 1, except that only the first adhesion reinforcement layer 15 is provided between the box dam 14 and the first substrate 11, as shown in FIG. 5. For the relevant features of the adhesion enhancement layer, please refer to the description about the aforementioned embodiment shown in FIG. 1.

According to yet another embodiment of the present disclosure, an OLED panel is provided. This embodiment is an extension of the aforementioned embodiment shown in FIG. 1, it is substantially the same as the main structure of the aforementioned embodiment shown in FIG. 1, except that only the second adhesion reinforcement layer 16 is provided between the box dam 14 and the second substrate 13, as shown in FIG. 6. For the relevant features of the adhesion enhancement layer, please refer to the description about the aforementioned embodiment shown in FIG. 1.

In an embodiment of the present disclosure, it also provides an OLED display apparatus, including the OLED panel according to any one of the aforementioned embodiments. Since the OLED panel has the effects as described above, the structure of the OLED display apparatus can also improve the adhesion force of the box dam to the substrate, and effectively improve the level of reliability.

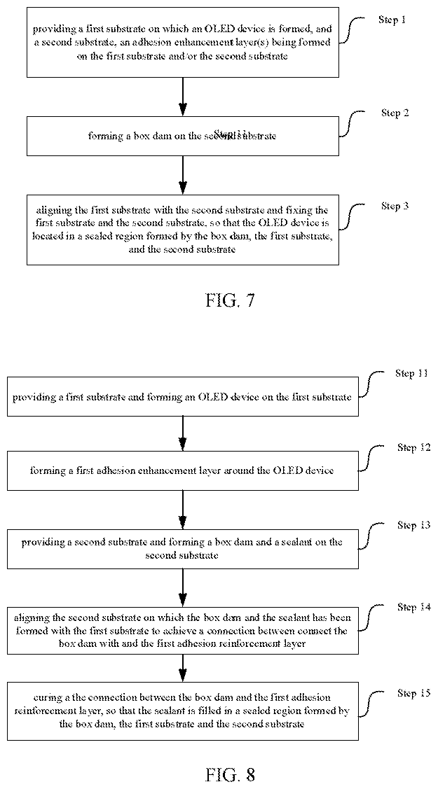

In an embodiment of the present disclosure, it also provides an OLED panel packaging method, which can obtain the OLED panel described in any one of the aforementioned embodiments. As shown in FIG. 7, the method mainly includes:

Step 1: providing a first substrate on which an OLED device is formed, and a second substrate, an adhesion enhancement layer being formed on the first substrate and/or the second substrate;

Step 2: forming a box dam on the second substrate:

Step 3: aligning the first substrate with the second substrate and fixing the first substrate and the second substrate, so that the OLED device is located in a sealed region formed by the box dam, the first substrate, and the second substrate.

For the characteristics of the adhesion enhancement layer, reference may be made to the description about the aforementioned embodiment shown in FIG. 1.

Several exemplary embodiments of an OLED panel packaging method will be specifically described below.

FIG. 8 is a flowchart of an OLED panel packaging method according to an exemplary embodiment of the present disclosure. In the exemplary embodiment shown in FIG. 8, an adhesion reinforcement layer is formed between the first substrate and the box dam. As shown in FIG. 8, the OLED panel packaging method includes the following steps.

Step 11: providing a first substrate and forming an OLED device on the first substrate.

The technology for forming the OLED device on the first substrate belongs to the prior art, and therefore it will not be repeated in the present disclosure.

Step 12, forming a first adhesion enhancement layer around the OLED device.

The adhesive force of the material of the first adhesion reinforcement layer is greater than or equal to twice the adhesive force of the material of the box dam. The material used for forming the adhesion enhancement layer includes one of the following: a resin-based material, an acrylic-based material, or a polyester material.

In one embodiment, the material of the adhesion enhancement layer may further include inorganic particles.

The first adhesion enhancement layer may be formed on the surface of the first substrate around the OLED device, or in the grooves formed by etching in the first substrate, or the protrusions coated on the first substrate, by spot coating, spray coating, or coating. For details, please refer to the description of the aforementioned embodiment shown in FIG. 1.

Step 13: providing a second substrate and forming a box dam and a sealant on the second substrate.

The sealant is used to fill the closed space formed by the box dam, the first substrate and the second substrate, and the technology for forming the box dam and the sealant on the substrate belongs to the prior art, and therefore it will not be repeated here.

The implementation order of the above Steps 12 and 13 is not limited thereto.

Step 14: aligning the second substrate on which the box dam and the sealant has been formed with the first substrate to achieve a connection between the box dam and the first adhesion reinforcement layer.

In this step, the alignment and the connection may be performed by a pressing process.

Step 15: curing the connection between the box dam and the first adhesion reinforcement layer, so that the sealant is filled in a sealed region formed by the box dam, the first substrate and the second substrate.

In this step, a UV light curing process may be used for curing.

In this exemplary embodiment, by constructing a high-adhesive adhesion reinforcement layer between the first substrate and the box dam, and by utilizing the good adhesion of the high-adhesive material, it improves the adhesion force of the box dam to the first substrate and effectively improves the level of reliability.

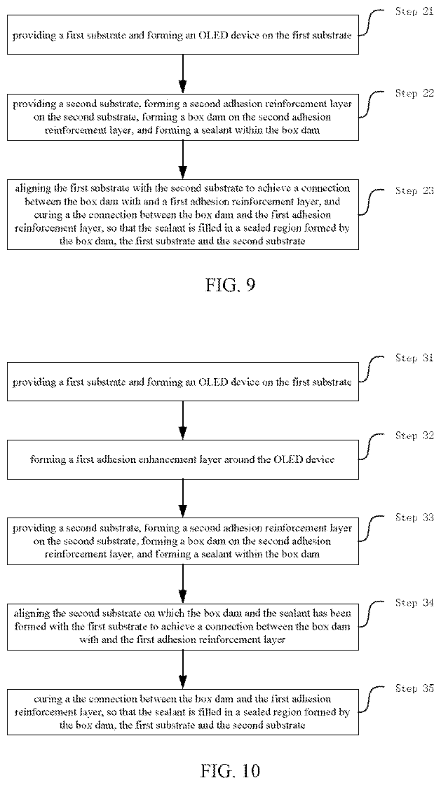

FIG. 9 is a flowchart of an OLED panel packaging method according to another exemplary embodiment of the present disclosure. In the exemplary embodiment shown in FIG. 9, an adhesion reinforcement layer is formed between the second substrate and the box dam. As shown in FIG. 9, the OLED panel packaging method includes the following steps.

Step 21: providing a first substrate and forming an OLED device on the first substrate;

Step 22: providing a second substrate, forming a second adhesion reinforcement layer on the second substrate, forming a box dam on the second adhesion reinforcement layer, and forming a sealant within the box dam.

The second adhesion enhancement layer may be formed on the surface of the second substrate, or in the grooves formed by etching in the second substrate, or the protrusions coated on the second substrate, by spot coating, spray coating, or coating. For details, please refer to the description of the first embodiment.

The method of forming the box dam and the sealant may be implemented by using the existing technology, and therefore it will not be repeated here.

Step 23: aligning the first substrate with the second substrate to achieve a connection between the box dam and a first adhesion reinforcement layer, and curing the connection between the box dam and the first adhesion reinforcement layer, so that the sealant is filled in a sealed region formed by the box dam, the first substrate and the second substrate.

In this exemplary embodiment, by constructing a high-adhesive adhesion reinforcement layer between the second substrate and the box dam, and by utilizing the good adhesion of the high-adhesive material, it improves the adhesion force of the box dam to the second substrate and effectively improves the level of reliability.

FIG. 10 is a flowchart of an OLED panel packaging method according to yet another exemplary embodiment of the present disclosure. The exemplary embodiment shown in FIG. 10 is a combination of the exemplary embodiment shown in FIG. 8 and the exemplary embodiment shown in FIG. 9, that is, adhesion reinforcement layers are respectively formed between the first substrate and the box dam, and between the second substrate and the box dam. As shown in FIG. 10, the OLED panel packaging method includes the following steps.

Step 31: providing a first substrate and forming an OLED device on the first substrate;

Step 32: forming a first adhesion enhancement layer around the OLED device.

The first adhesion enhancement layer may be formed on the surface of the first substrate around the OLED device, or in the grooves formed by etching in the first substrate, or the protrusions coated on the first substrate, by spot coating, spray coating, or coating.

Step 33: providing a second substrate, forming a second adhesion reinforcement layer on the second substrate, forming a box dam on the second adhesion reinforcement layer, and forming a sealant within the box dam.

The second adhesion reinforcement layer may be formed by spot coating, spray coating, or coating.

The implementation order of the above Steps 31, 32 and 33 is not limited thereto, for example, the Step 33 may be implemented first, and then the Steps 31 and 32 are implemented.

Step 14: aligning the second substrate on which the box dam and the sealant has been formed with the first substrate to achieve a connection between the box dam and the first adhesion reinforcement layer;

Step 15: curing the connection between the box dam and the first adhesion reinforcement layer, so that the sealant is filled in a sealed region formed by the box dam, the first substrate and the second substrate.

In this exemplary embodiment, by constructing high-adhesion adhesion reinforcement layers between the first substrate and the box dam and between the second substrate and the box dam, and by utilizing the good adhesion of the high-adhesive material, it improves the adhesion force of the box dam to the first substrate and the adhesion force of the box dam to the second substrate, and effectively improves the level of reliability.

### Application Examples

In the following, it is described by taking that the light emitting device is an OLED device, the first substrate is a substrate made of glass, the second substrate is a cover plate made of glass, and the adhesion reinforcement layer is a high-adhesive sealant component as an example.

As shown in FIG. 1, the OLED packaging structure includes a box dam 14, a sealant 17, and high-adhesive sealant components 15 and 16, wherein the box dam 14 limits the sealing range of the OLED device 12, the sealant 17 is filled in the region sealed by the substrate 11, the cover plate 13 and the box dam 14, and the box dam 14 directly contacts the outside and the sealant 17. The contact regions of the box dam 14 with the base plate 11 and the cover plate 13 includes high-adhesive sealant components 15 and 16. The adhesion force of the high-adhesive sealant component to the base plate and cover plate is greater than or equal to twice the adhesion force of the box dam to the base plate and cover plate, for example, it is greater than 50 kg/cm², and the high-adhesive sealant components may exist on the base plate and cover plate in a dot or linear manner.

The high-adhesive sealant components may be achieved by fixed-point coating methods such as dispenser, Ink Jet Printing (UP), or coating.

The arrangement pattern of the high-adhesive sealant components is not limited, and it may be a uniform dotted arrangement.

The high-adhesive sealant may be a resin-based material, an acrylic-based material, or a polyester material. Compared with conventional materials, these materials have good adhesion and low WVTR. Due to its high adhesion, it raises high requirements for glue coating equipment. A short-distance coating may be used without need for long-distance stability, reducing the need for the equipment. Using these materials to connect the glass to the conventional box dam, it can improve the adhesion force and barrier property of the overall structure. For example, inorganic particles (for example, calcium oxide (CaO) inorganic particles) nay also be added to the high-adhesive sealant to form a denser structure without taking into account the coating property. It has the same curing condition as the box dam. After the structure is built, they may be cured together.

By using high-adhesive property to effectively connect the sealant to the substrate and the cover plate, while forming a concave-convex structure (for example, an uneven structure composed of grooves and/or protrusions), it increases the contact area of the box dam, increases the adhesion ability, and improves the level of reliability.

In summary, in the OLED panel, the display apparatus and the panel packaging method according to this embodiment, by providing an adhesion reinforcement layer between the box dam and the substrate and by using the adhesion reinforcement layer to improve the sealing effect of the box dam, it effectively improves the level of reliability of the structure. Of course, implementing any of the products or methods in the present disclosure does not necessarily need to achieve all the advantages described above at the same time.

Although the embodiments disclosed in the present disclosure are as described above, the described contents only refer to the embodiments that are provided to facilitate the understanding of the present disclosure, but they are not intended to limit the present disclosure. Any modifications and changes may be made by those skilled in the art in the form and details of the embodiments without departing from the spirit and scope of the present disclosure, but the scope of the present disclosure is still defined by the appended claims.

The above embodiments are only exemplary embodiments of the present disclosure but are not used to limit the present disclosure, and the scope of the present disclosure is defined by the claims. The various modifications or equivalent replacements to the present disclosure made by those skilled in the art within the spirit and scope of the present disclosure shall fall within the scope of the present disclosure.

1. An OLED panel, comprising:
a first substrate on which an OLED device is provided;
a second substrate opposite to the first substrate;
a box dam connected to the first substrate and the second substrate,
wherein the OLED device is located in a sealed region formed by the box dam, the first substrate and the second substrate;
wherein an adhesion reinforcement layer is provided between the box dam and the first substrate or between the box dam and the second substrate, or adhesion reinforcement layers are respectively provided between the box dam and the first substrate and between the box dam and the second substrate;
wherein an adhesive force of a material of the adhesion reinforcement layer is greater than or equal to twice an adhesive force of a material of the box dam.

2. (canceled)

3. The OLED panel according to claim 1, wherein a material of the adhesion reinforcement layer comprises one of the following: a resin-based material, an acrylic-based material, or a polyester material.

4. The OLED panel according to claim 3, wherein fine particles are provided in the adhesion enhancement layer.

5. The OLED panel according to claim 4, wherein a material of the fine particles comprises an inorganic material.

6. The OLED panel according to claim 1, wherein the adhesion reinforcement layer is in a dotted arrangement or a linear arrangement in a plane parallel to the first substrate and/or the second substrate.

7. The OLED panel according to claim 1, wherein
in a plane perpendicular to the first substrate and/or the second substrate, the adhesion reinforcement layer has a cross-sectional shape of rectangle, semicircle, trapezoid, or triangle.

8. The OLED panel according to claim 1, wherein
in a plane perpendicular to the first substrate, a contact surface of the adhesion reinforcement layer and the first substrate has a concave-convex stricture; and/or
in a plane perpendicular to the second substrate, a contact surface of the adhesion reinforcement layer and the second substrate has a concave-convex structure.

9. An OLED display apparatus, comprising the OLED panel according to claim 1.

10. An OLED panel packaging method, comprising:
providing a first substrate on which an OLED device is formed, and a second substrate, an adhesion enhancement layer(s) being formed on the first substrate and/or the second substrate;
forming a box dam on the second substrate;
aligning the first substrate with the second substrate and fixing the first substrate and the second substrate, so that the OLED device is located in a sealed region formed by the box dam, the first substrate, and the second substrate.

11. The packaging method according to claim 10, wherein the adhesion enhancement layer is formed by spot coating, spray coating, or coating.

12. The packaging method according to claim 10, wherein an adhesive force of a material of the adhesion reinforcement layer is greater than or equal to twice an adhesive force of a material of the box dam.

13. The packaging method according to claim 10, wherein a material of the adhesion reinforcement layer comprises one of the following: a resin-based material, an acrylic-based material, or a polyester material.

14. The packaging method according to claim 10, wherein
the adhesion reinforcement layer is in a dotted arrangement or a linear arrangement in a plane parallel to the first substrate and/or the second substrate,
in a plane perpendicular to the first substrate and/or the second substrate, the adhesion reinforcement layer has a cross-sectional shape of rectangle, semicircle, trapezoid, or triangle.

15. The packaging method according to claim 10, wherein
in a plane perpendicular to the first substrate, a contact surface of the adhesion reinforcement layer and the first substrate has a concave-convex structure; and/or
in a plane perpendicular to the second substrate, a contact surface of the adhesion reinforcement layer and the second substrate has a concave-convex structure.

16. A packaging method for the OLED panel according to claim 1, comprising:
providing the first substrate and forming the OLED device on the first substrate;
forming a first adhesion enhancement layer around the OLED device;
providing the second substrate and forming the box dam and the sealant on the second substrate;
aligning the second substrate on which the box dam and the sealant has been formed with the first substrate to achieve a connection between the box dam and the first adhesion reinforcement layer; and
curing the connection between the box dam and the first adhesion reinforcement layer, so that the sealant is filled in a sealed region formed by the box dam, the first substrate and the second substrate.

17. A packaging method for the OLED panel according to claim 1, comprising:
providing the first substrate and forming the OLED device on the first substrate;
providing the second substrate, forming a second adhesion reinforcement layer on the second substrate, forming the box dam on the second adhesion reinforcement layer, and forming the sealant within the box dam; and
aligning the first substrate with the second substrate to achieve the connection between the box dam and a first adhesion reinforcement layer, and curing the connection between the box dam and the first adhesion reinforcement layer, so that the sealant is filled in a sealed region formed by the box dam, the first substrate and the second substrate.

18. A packaging method for the OLED panel according to claim 1, comprising:
providing the first substrate and forming the OLED device on the first substrate;
forming a first adhesion enhancement layer around the OLED device;
providing the second substrate, forming a second adhesion reinforcement layer on the second substrate, forming the box dam on the second adhesion reinforcement layer, and forming the sealant within the box dam;
aligning the second substrate on which the box dam and the sealant has been formed with the first substrate to achieve the connection between the box dam and the first adhesion reinforcement layer; and
curing the connection between the box dam and the first adhesion reinforcement layer, so that the sealant is filled in a sealed region formed by the box dam, the first substrate and the second substrate.
